(19) United States
(12) Patent Application Publication
(10) Pub. No.: US 2014/0191217 A1
(43) Pub. Date: Jul. 10, 2014

(54) ORGANIC ELECTROLUMINESCENT DISPLAY DEVICE

(71) Applicant: WINTEK CORPORATION, Taichung City (TW)

(72) Inventors: Chien-Chung Chen, Taichung City (TW); Hen-Ta Kang, Taichung City (TW)

(73) Assignee: WINTEK CORPORATION, Taichung City (TW)

(21) Appl. No.: 14/148,740

(22) Filed: Jan. 7, 2014

(30) Foreign Application Priority Data
Jan. 8, 2013 (TW) 102100614

(51) Int. Cl. H01L 27/32

(52) U.S. Cl. CPC H01L 27/3232; H01L 27/3227
USPC 257/40

(57) ABSTRACT

An organic electroluminescent display device includes an organic light emitting structure, a back light module, and a light control structure. The organic light emitting structure includes a first electrode, a second electrode, an organic light emitting layer, and a photo current sensitive layer. The back light module is disposed correspondingly to the organic light emitting structure so as to provide a light beam to the organic light emitting structure. The photo current sensitive layer is configured to absorb the light beam for generating an electrical current, and the electrical current is configured to drive the organic light emitting layer. The light control structure is disposed between the organic light emitting structure and the back light module as so to control amount of the light beam entering the organic light emitting structure.

### BACKGROUND OF THE INVENTION

1. Field of the Invention

The present invention relates to an organic electroluminescent display device, and more particularly, to an organic electroluminescent display device including a photo current sensitive layer configured to absorb a light beam from a back light module and generate an electrical current for driving an organic light emitting layer.

2. Description of the Prior Art

Electroluminescent display device, which has the advantages of absence of color filter, self-luminescence, and low power consumption, is always viewed as the best candidate to substitute for the liquid crystal display and become the main display technology of the next generation. Organic electroluminescent display is a relatively mature technology amount each kinds of the electroluminescent displays.

In common organic electroluminescent display devices, organic light emitting materials are driven by electrical currents, and a stability of the electrical currents provided by driving units has been seriously demanded. Amorphous silicon thin film transistors (a-Si TFTs) and poly silicon thin film transistors are common driving units in the related industries. The amorphous silicon thin film transistor is currently the mainstream thin film transistor applied in the display industry because of its mature process techniques and high yield. However, the amorphous silicon thin film transistor is not suitable for driving the organic light emitting materials because a threshold voltage shift issue is more serious in the amorphous silicon thin film transistor. On the contrary, the threshold voltage shift issue is relatively minor in the poly silicon thin film transistor, but complicated compensation circuit designs such as 2T1C (2 transistors with 1 capacitance) are still required to drive the organic light emitting materials. The compensation circuit designs may influence aperture ratio and manufacturing yield about the organic electroluminescent display devices. In addition, because of process issues such as high process complexity and worse uniformity, which is mainly generated by crystallization processes applied to large size substrates, the poly silicon thin film transistors are mainly applied in small size display devices and the high manufacturing cost of the poly silicon thin film transistors is still a problem to be solved.

### SUMMARY OF THE INVENTION

It is one of the objectives of the present invention to provide an organic electroluminescent display device. A light control structure is used to control amount of a light beam generated from a back light source and entering a photo current sensitive layer. The photo current sensitive layer is used to absorb the light beam from the back light module and generate an electrical current for driving an organic light emitting layer and generating display effects. A condition of the electrical current may be controlled by the amount of the light beam passing through the light control structure.

To achieve the purposes described above, a preferred embodiment of the present invention provides an organic electroluminescent display device. The organic electroluminescent display device includes an organic light emitting structure, a back light module, and a light control structure. The organic light emitting structure includes a first electrode, a second electrode, an organic light emitting layer, and a photo current sensitive layer. The second electrode is disposed oppositely to the first electrode. The organic light emitting layer is disposed between the first electrode and the second electrode. The photo current sensitive layer is disposed between the organic light emitting layer and the first electrode. The back light module is disposed correspondingly to the organic light emitting structure. The back light module is configured to provide a light beam to the organic light emitting structure. The photo current sensitive layer is configured to absorb the light beam for generating an electrical current, and the electrical current is configured to drive the organic light emitting layer. The light control structure is disposed between the organic light emitting structure and the back light module. The light control structure is configured to control amount of the light beam entering the organic light emitting structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an organic electroluminescent display device according to a first preferred embodiment of the present invention.

FIG. 2 is a schematic diagram illustrating an organic electroluminescent display device according to a second preferred embodiment of the present invention.

FIG. 3 is a schematic diagram illustrating a display conduction of the organic electroluminescent display device according to the second preferred embodiment of the present invention.

FIG. 4 is a schematic diagram illustrating an organic electroluminescent display device according to a third preferred embodiment of the present invention.

FIG. 5 is a schematic diagram illustrating an organic electroluminescent display device according to a fourth preferred embodiment of the present invention.

FIG. 6 is a schematic diagram illustrating an organic electroluminescent display device according to a fifth preferred embodiment of the present invention.

FIG. 7 is a schematic diagram illustrating an organic electroluminescent display device according to a sixth preferred embodiment of the present invention.

### DETAILED DESCRIPTION

To provide a better understanding to skilled users in the technology, the embodiments will be detailed as follows. The embodiments are illustrated in the accompanying drawings with numbered elements to elaborate the contents and effects to be achieved.

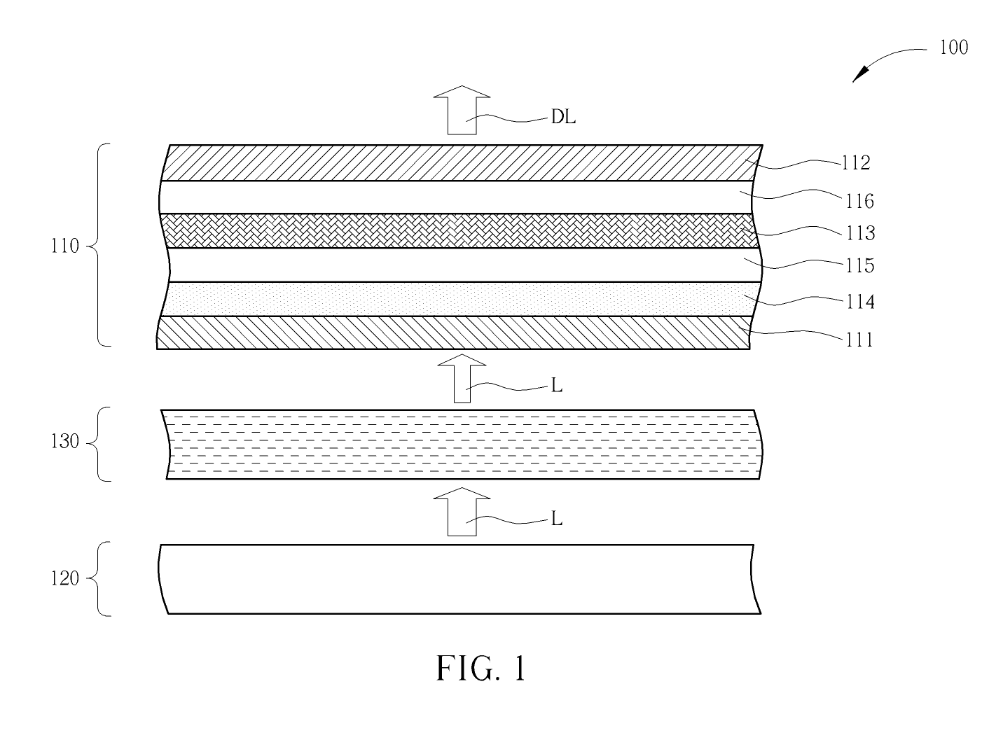

Please refer to FIG. 1. FIG. 1 is a schematic diagram illustrating an organic electroluminescent display device according to a first preferred embodiment of the present invention. Please note that the figures are only for illustration and the figures may not be to scale. The scale maybe further modified according to different design considerations. As shown in FIG. 1, an organic electroluminescent display device 100 is provided in this embodiment. The organic electroluminescent display device 100 includes an organic light emitting structure 110, a back light module 120, and a light control structure 130. The organic light emitting structure 110 includes a first electrode 111, a second electrode 112, an organic light emitting layer 113, and a photo current sensitive layer 114. The second electrode 112 is disposed oppositely to the first electrode 111. In this embodiment, the first electrode 111 is preferably an anode electrode and the second electrode 112 is preferably a cathode electrode, but not limited thereto. For example, in other preferred embodiments of the present invention, the first electrode 111 may also be a cathode electrode and the second electrode 112 may be an anode electrode according to other design considerations. The organic light emitting layer 113 is disposed between the first electrode 111 and the second electrode 112. The photo current sensitive layer 114 is disposed between the organic light emitting layer 113 and the first electrode 111. The back light module 120 is disposed correspondingly to the organic light emitting structure 110. The back light module 120 is configured to provide a light beam L to the organic light emitting structure 110. The back light module 120 in this embodiment may include an edge lighting back light module or a direct lighting back light module, but not limited thereto. The photo current sensitive layer 114 is configured to absorb the light beam L for generating an electrical current, and the electrical current is configured to drive the organic light emitting layer 113. In other words, the light beam L provided by the back light module 120 may be absorbed by the photo current sensitive layer 114 for generating an electrical current configured to drive the organic light emitting layer 113 and generate a display light beam DL. It is worth noting that the present invention is not limited to the stacking order of the first electrode 111, the second electrode 112, the organic light emitting layer 113, and the photo current sensitive layer 114 described above. In other preferred embodiments of the present invention, the stacking order of the first electrode 111, the second electrode 112, the organic light emitting layer 113, and the photo current sensitive layer 114 maybe further modified according to other considerations.

In this embodiment, the back light module 120 may preferably include an invisible light back light module such as an infrared back light module, and the light beam L may preferably include an invisible light such as an infrared light beam, but not limited thereto. The display light beam DL may not be influenced by the light beam L when the light beam L is an invisible light . Additionally, the light control structure 130 is disposed between the organic light emitting structure 110 and the back light module 120. The light control structure 130 is configured to control amount of the light beam L generated from the back light module 120 and entering the organic light emitting structure 110. A condition of the electrical current generated by the photo current sensitive layer 114 may then be controlled by the amount of the light beam L entering the organic light emitting structure 110. In other words, the display light beams DL in different gray scales maybe generated by the organic light emitting structure 110 when the organic light emitting layer 113 is driven by the electrical currents generated from the photo current sensitive layer 114 in different magnitude which may be controlled by the amount of the light beam L entering the organic light emitting structure 110. In this embodiment, the light control structure 130 may preferably include a micro electro mechanical system (MEMS) shutter device, a liquid crystal panel, an electro-wetting panel, an electrochromic device, or other appropriate light control structures. Additionally, the organic light emitting structure 110 may further include a hole transport layer 115 and an electron transport layer 116, but not limited thereto. The hole transport layer 115 is disposed between the organic light emitting layer 113 and the photo current sensitive layer 114. The electron transport layer 116 is disposed between the organic light emitting layer 113 and the second electrode 112. In other preferred embodiments of the present invention, an hole injection layer or other required material layers may also be disposed in the organic light emitting structure 110 so as to further modify light emitting properties according to other design considerations. It is worth noting that the photo current sensitive layer 114 may preferably include a photo current sensitive material such as a tin phthalocyanine (SnPc) or a mixed film of SnPc and carbon-60 (SnPc:C₆₀ mixed film) when the back light module 120 is an infrared back light module, but not limited thereto. In other preferred embodiments of the present invention, components of the photo current sensitive layer 114 maybe further modified according to different properties of the light beam L generated from the back light module 120 so as to generate required photo current effects.

The following description will detail the different embodiments of the organic electroluminescent display device in the present invention. To simplify the description, the identical components in each of the following embodiments are marked with identical symbols. For making it easier to compare the difference between the embodiments, the following description will detail the dissimilarities among different embodiments and the identical features will not be redundantly described.

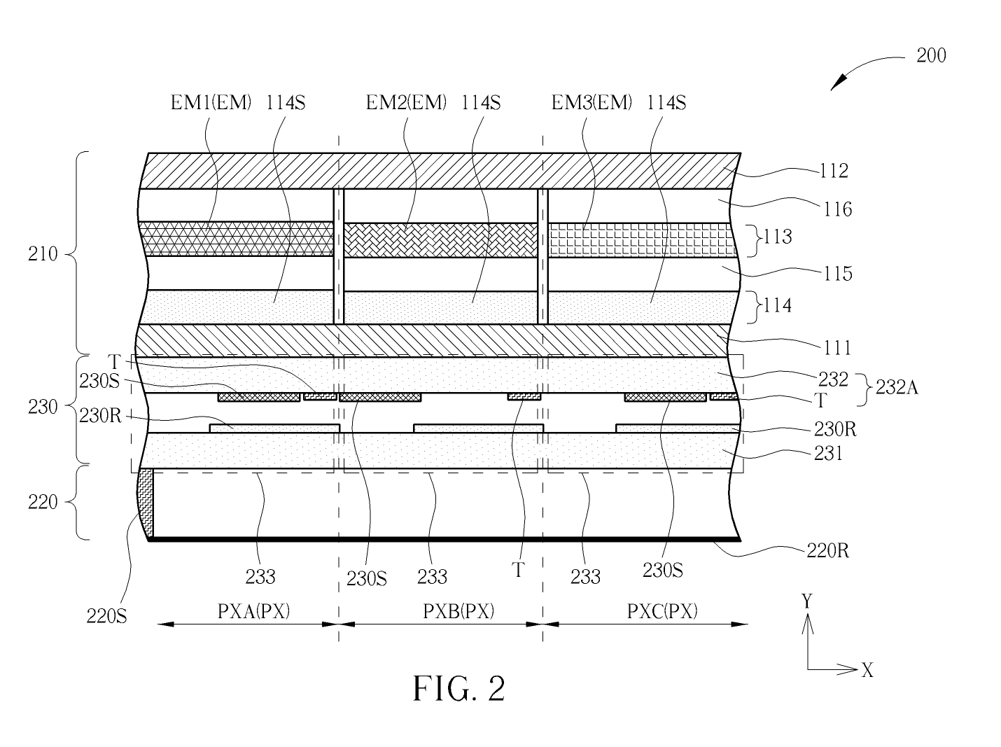

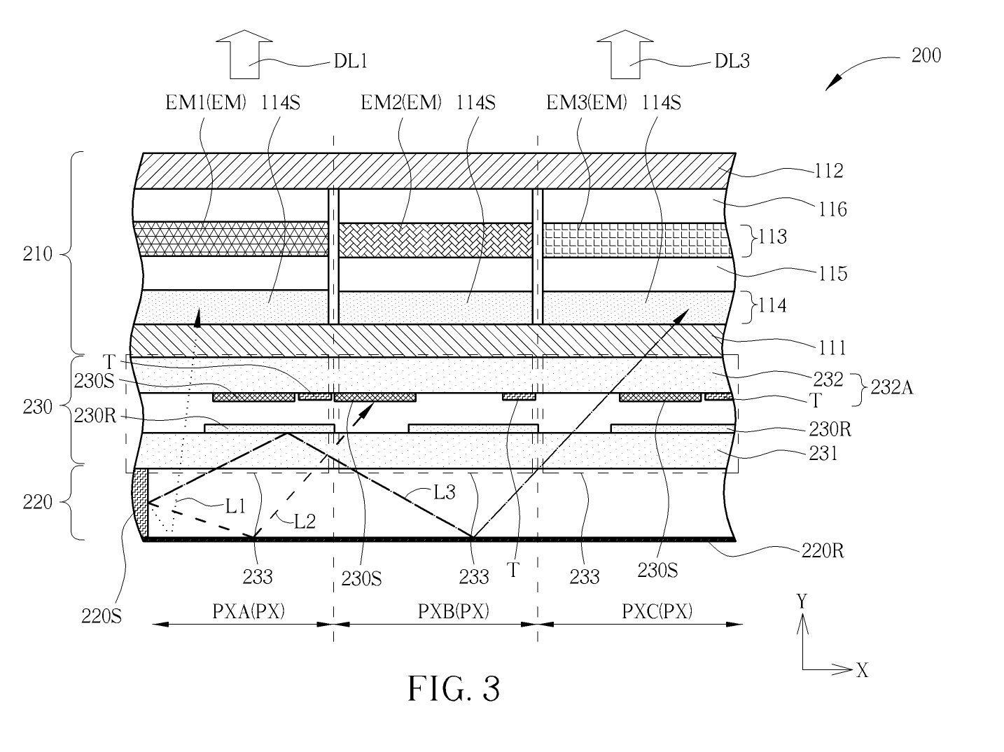

Please refer to FIG. 2 and FIG. 3. FIG. 2 is a schematic diagram illustrating an organic electroluminescent display device according to a second preferred embodiment of the present invention. FIG. 3 is a schematic diagram illustrating a display conduction of the organic electroluminescent display device in this embodiment. As shown in FIG. 2, an organic electroluminescent display device 200 is provided in this embodiment. The organic electroluminescent display device 200 includes an organic light emitting structure 210, a back light module 220, and a light control structure 230. The difference between the organic electroluminescent display device 200 in this embodiment and the first preferred embodiment detailed above is that the organic electroluminescent display device 200 further includes a plurality of sub-pixel regions PX. The organic light emitting layer 113 in the organic light emitting structure 210 includes a plurality of organic light emitting units EM respectively disposed in the sub-pixel regions PX, and the organic light emitting units EM are used to generate display light beams in different colors, but not limited thereto. For example, the sub-pixel regions PX may include a first sub-pixel region PXA, a second sub-pixel region PXB, and a third sub-pixel region PXC disposed adjacently to one another. The organic light emitting units EM may include a first organic light emitting unit EM1, a second organic light emitting unit EM2, and a third organic light emitting unit EM3 respectively disposed in the first sub-pixel region PXA, the second sub-pixel region PXB, and the third sub-pixel region PXC. The first organic light emitting unit EM1, the second organic light emitting unit EM2, and the third organic light emitting unit EM3 may be a red organic light emitting unit, a green organic light emitting unit, and a blue organic light emitting unit respectively. The first sub-pixel region PXA, the second sub-pixel region PXB, and the third sub-pixel region PXC may then emit a red light beam, a green light beam, and a blue light beam respectively, and a full color display effect may be achieved by mixing the light beams in different colors. Additionally, in the organic light emitting structure 210, the photo current sensitive layer 114 may preferably include a plurality of photo current sensitive units 114S respectively disposed in the sub-pixel regions PX, and each of the photo current sensitive units 114S are electrically isolated from one another so as to avoid interference between the photo current sensitive layer 114 in each of the sub-pixel regions PX, but not limited thereto. In this embodiment, the first electrode 111 and the second electrode 112 may be disposed in all of the sub-pixel regions PX so as to simplify the structure and a driving approach.

In this embodiment, the light control structure 230 is preferably a MEMS shutter device, and the light control structure 230 includes a plurality of sub units 233 respectively disposed in the sub-pixel regions PX. The subunits 233 are configured to control the amount of the light beam generated from the back light module 220 and entering each of the photo current sensitive units 114S. For example, the light control structure 230 in this embodiment may include a lower substrate 231, an upper substrate 232, a reflecting plate 230R, a plurality of shielding plates 230S, and a plurality of switching units T. The reflecting plate 230R, the shielding plates 230S, and the switching units T are disposed between the lower substrate 231 and the upper substrate 232. The reflecting plates 230R are used to partially block light beams from the back light module 200 and define a maximum aperture in each of the sub units 233. The shielding plates 230S and the switching units T are disposed in each of the sub units 233 respectively. The aperture in each of the sub units 233 may be changed by controlling positions of the shielding plates 230S along a horizontal direction X in each of the sub units 233 with the switching units T. As shown in FIG. 3, the back light module 220 in this embodiment is an edge lighting back light module, but not limited thereto. The back light module 220 may include a light source 220S disposed on a side of the back light module 220. Light beams generated from the light source 220S may be guided substantially toward a vertical direction Y by a reflecting surface 220R in the back light module 220. In the light control structure 230, the amount of the light beams passing through each of the sub units 233 and entering each of the photo current sensitive units 114 may be controlled by modifying the positions of the shielding plates 230S along the horizontal direction X in each of the sub units 233. For example, as shown in FIG. 3, the shielding plates 230S in the first sub-pixel region PXA and the third sub-pixel region PXC may shift rightward, and regions uncovered by the reflecting plate 230R along the vertical direction Y in the first sub-pixel region PXA and the third sub-pixel region PXC are also not covered by the shielding plates 230S and present open states. A light beam L1 and a light beam L3 irradiating toward the sub units 233 in the first sub-pixel region PXA and the third sub-pixel region PXC may pass through the sub units 233 and enter the corresponding photo current sensitive units 114S. The photo current sensitive units 114S in the first sub-pixel region PXA and the third sub-pixel region PXC may then generate electrical currents for driving the first organic light emitting unit EM1 and the third organic light emitting unit EM3, and the first sub-pixel region PXA and the third sub-pixel region PXC may respectively generate a display light beam DL1 and a display light beam DL3 accordingly.

On the contrary, as shown in FIG. 3, the shielding plate 230S in the second sub-pixel region PXB may shift leftward, and regions uncovered by the reflecting plate 230R along the vertical direction Y in the second sub-pixel region PXB may be covered by the shielding plate 230S and present an close state. A light beam L2 irradiating toward the sub unit 233 in the second sub-pixel region PXB may not pass through the sub units 233, and the photo current sensitive unit 114S in the second sub-pixel region PXB may not be irradiated by the light beam L2 from the back light module 220. In other words, the shifting conditions of the shielding plates 230S may be used to change the aperture conditions in the sub units 122, and the amount of the light beams entering the photo current sensitive units 114 may be controlled accordingly. The display light beams in different gray scales may be generated by the organic light emitting units EM when the organic light emitting units EM are driven with electrical currents in different magnitude generated from the photo current sensitive units 114. It is worth noting that the reflecting plate 230R may also be used to recycle a light beam which does not directly enter the organic light emitting structure 210 (such as the light beam L3 in FIG. 3), and the luminous efficiency may be enhanced accordingly. In this embodiment, each of the switching units T may include a thin film transistor disposed on the upper substrate 232 so as to form an array substrate 232A, but not limited thereto. In other words, the light control structure 230 may include the array substrate 232A, and the array substrate 232A, may include a plurality of the switching units T configured to control the amount of the light beams passing through each of the sub units 233 and entering the organic light emitting structure 210. Because the switching units T are used to control the positions of the shielding plates 230S along the horizontal direction X, amorphous silicon thin film transistors may be used as the switching units T, and the purposes of process simplification and cost reduction may then be achieved.

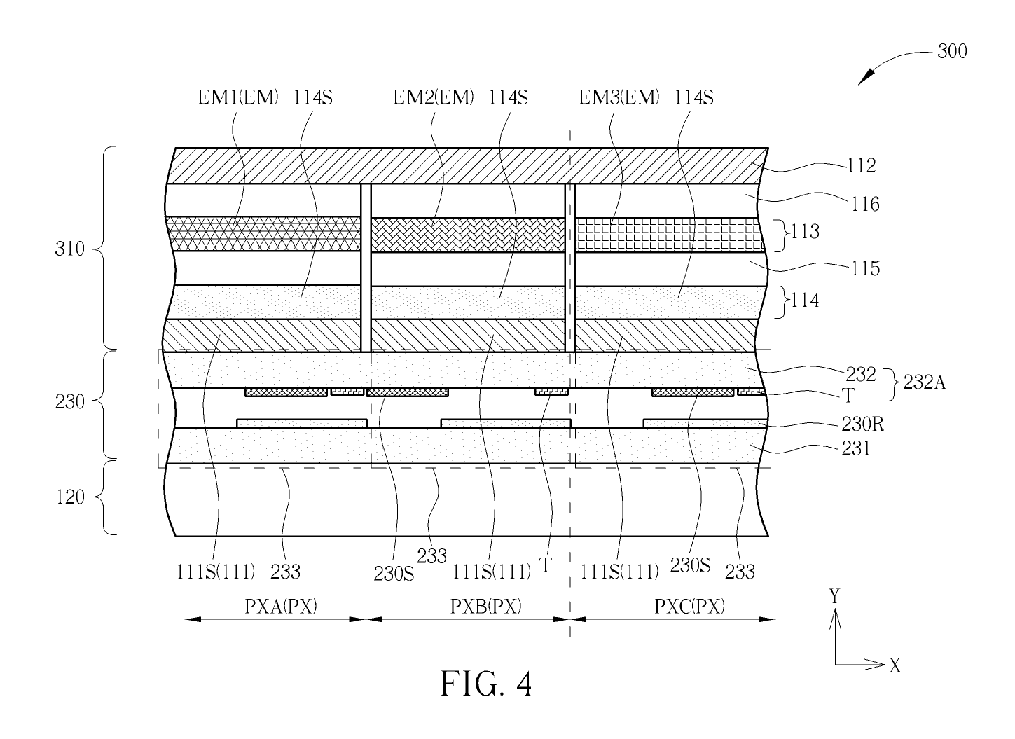

Please refer to FIG. 4. FIG. 4 is a schematic diagram illustrating an organic electroluminescent display device according to a third preferred embodiment of the present invention. As shown in FIG. 4, an organic electroluminescent display device 300 is provided in this embodiment. The organic electroluminescent display device 300 includes an organic light emitting structure 310, the back light module 120, and the light control structure 230. The difference between the organic electroluminescent display device 300 in this embodiment and the second preferred embodiment detailed above is that the first electrode 111 in the organic light emitting structure 310 includes a plurality of first sub electrodes 111S respectively disposed in the sub-pixel regions PX. The first sub electrodes 111S are electrically isolated from one another. Accordingly, electrical voltage conditions between the first electrode 111 and the second electrode 112 in each of the sub-pixel regions PX may be controlled independently, and the display conditions of each sub-pixel region PX may be controlled more precisely. Apart from the first sub electrodes 111S in this embodiment, the other components, allocations, material properties, and display approaches of this embodiment are similar to those of the second preferred embodiment detailed above and will not be redundantly described.

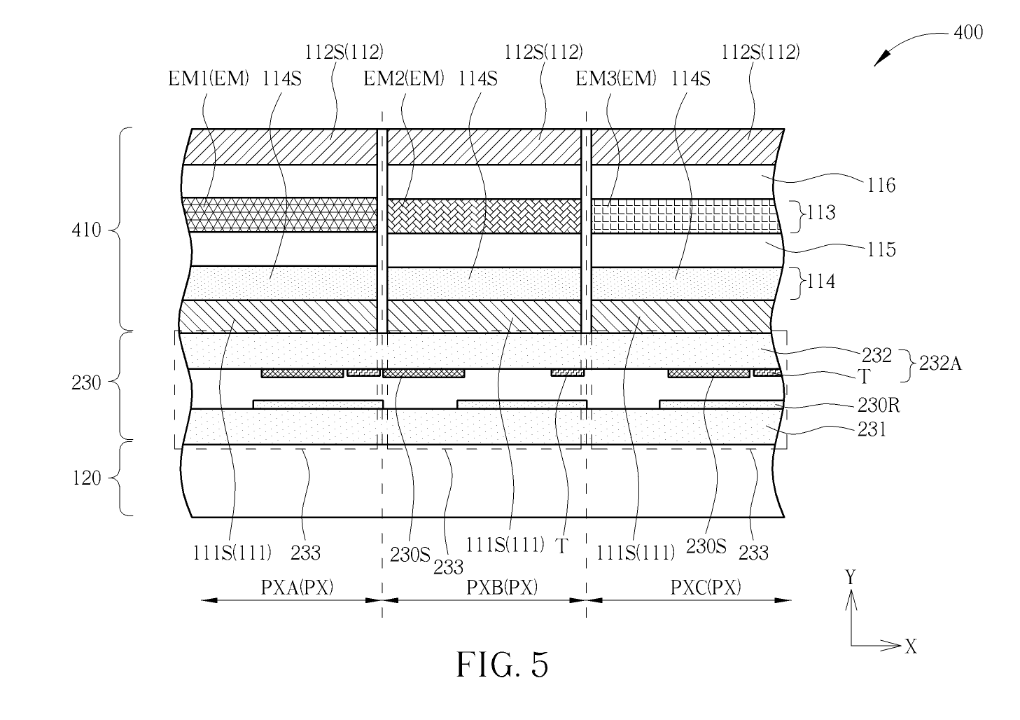

Please refer to FIG. 5. FIG. 5 is a schematic diagram illustrating an organic electroluminescent display device according to a fourth preferred embodiment of the present invention. As shown in FIG. 5, an organic electroluminescent display device 400 is provided in this embodiment. The organic electroluminescent display device 400 includes an organic light emitting structure 410, the back light module 120, and the light control structure 230. The difference between the organic electroluminescent display device 400 in this embodiment and the third preferred embodiment detailed above is that the second electrode 112 in the organic light emitting structure 410 includes a plurality of second sub electrodes 112S respectively disposed in the sub-pixel regions PX. The second sub electrodes 112S are electrically isolated from one another. Accordingly, electrical voltage conditions between the first sub electrodes 111S and the second sub electrode 112S in each of the sub-pixel regions PX may be controlled independently, and the display conditions of each sub-pixel region PX maybe controlled more precisely. Apart from the second sub electrodes 112S in this embodiment, the other components, allocations, material properties, and display approaches of this embodiment are similar to those of the third preferred embodiment detailed above and will not be redundantly described.

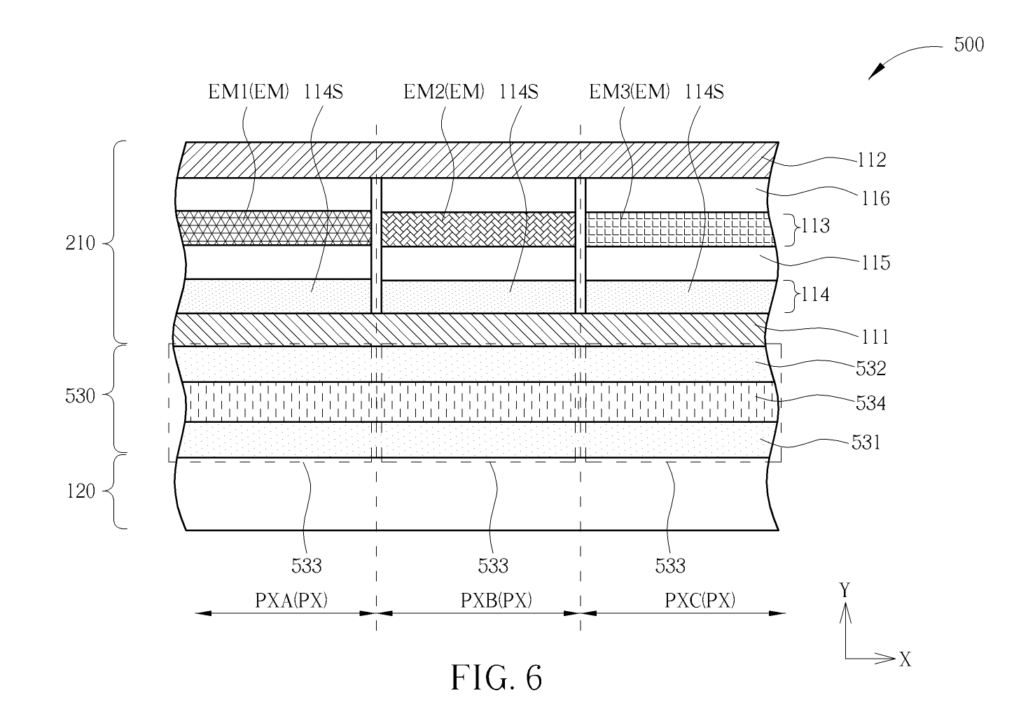

Please refer to FIG. 6. FIG. 6 is a schematic diagram illustrating an organic electroluminescent display device according to a fifth preferred embodiment of the present invention. As shown in FIG. 6, an organic electroluminescent display device 500 is provided in this embodiment. The organic electroluminescent display device 500 includes an organic light emitting structure 210, the back light module 120, and the light control structure 530. The difference between the organic electroluminescent display device 500 in this embodiment and the second preferred embodiment detailed above is that the light control structure 530 is preferably a liquid crystal panel. The light control structure 530 may include a plurality of sub units 533 respectively disposed in the sub-pixel regions PX so as to control the amount of the light beams generated from the back light module 120 and entering each of the photo current sensitive units 114S in the sub-pixel regions PX. For example, the light control structure 530 in this embodiment may include a lower substrate 531, an upper substrate 532, and a liquid crystal layer 534 disposed between the lower substrate 531 and the upper substrate 532. At least one of the upper substrate 532 and the lower substrate 531 may be an array substrate configured to drive the liquid crystal layer 534 in each of the sub units 533, and the amount of the light beams generated from the back light module 120 and entering the organic light emitting structure 210 through each of the sub units 533 may be accordingly controlled. Apart from the light control structure 530 in this embodiment, the other components, allocations, material properties, and display approaches of this embodiment are similar to those of the second preferred embodiment detailed above and will not be redundantly described.

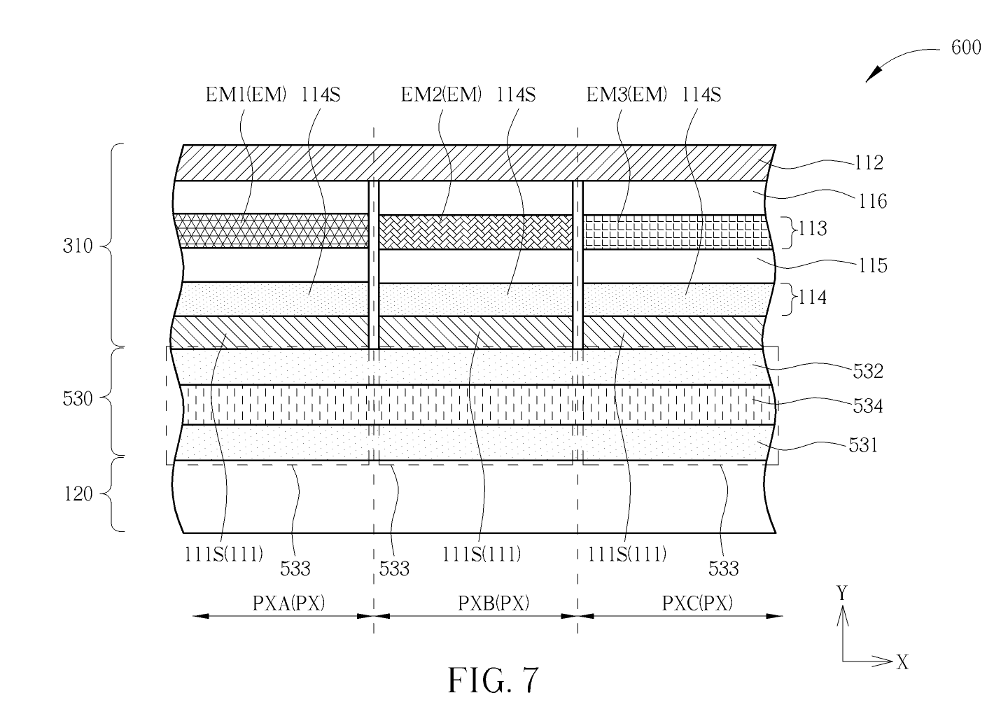

Please refer to FIG. 7. FIG. 7 is a schematic diagram illustrating an organic electroluminescent display device according to a sixth preferred embodiment of the present invention. As shown in FIG. 7, an organic electroluminescent display device 600 is provided in this embodiment. The organic electroluminescent display device 600 includes an organic light emitting structure 310, the back light module 120, and the light control structure 530. The difference between the organic electroluminescent display device 600 in this embodiment and the fifth preferred embodiment detailed above is that the first electrode 111 in the organic light emitting structure 310 includes a plurality of first sub electrodes 111S respectively disposed in the sub-pixel regions PX. The first sub electrodes 111S are electrically isolated from one another. Accordingly, electrical voltage conditions between the first electrode 111 and the second electrode 112 in each of the sub-pixel regions PX may be controlled independently, and the display conditions of each sub-pixel region PX may be controlled more precisely. Apart from the first sub electrodes 111S in this embodiment, the other components, allocations, material properties, and display approaches of this embodiment are similar to those of the fifth preferred embodiment detailed above and will not be redundantly described.

To summarize the above descriptions, in the organic electroluminescent display device of the present invention, the light control structure is used to control the amount of the light beam generated from the back light source and entering the photo current sensitive layer. The electrical current generated from the photo current sensitive layer by absorbing the light beam from the back light module may be controlled and used to drive the organic light emitting layer for generating display effects. Additionally, a MEMS shutter device or a liquid crystal panel may be used as the light control structure, and poly silicon thin film transistors formed by complicated processes will not be required for driving. Purposes of cost reduction and applications in large scale may be accordingly achieved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An organic electroluminescent display device, comprising:
an organic light emitting structure, comprising:
a first electrode;
a second electrode, disposed oppositely to the first electrode;
an organic light emitting layer, disposed between the first electrode and the second electrode; and
a photo current sensitive layer, disposed between the organic light emitting layer and the first electrode;
a back light module, disposed correspondingly to the organic light emitting structure, the back light module configured to provide a light beam to the organic light emitting structure; wherein the photo current sensitive layer is configured to absorb the light beam for generating an electrical current, and the electrical current is configured to drive the organic light emitting layer; and
a light control structure, disposed between the organic light emitting structure and the back light module, wherein the light control structure is configured to control amount of the light beam entering the organic light emitting structure.

2. The organic electroluminescent display device of claim 1, wherein the back light module comprises an infrared back light module, and the light beam comprises an infrared light beam.

3. The organic electroluminescent display device of claim 1, wherein the light control structure comprises a micro electro mechanical system (MEMS) shutter device or a liquid crystal panel.

4. The organic electroluminescent display device of claim 1, further comprising a plurality of sub-pixel regions, wherein the light control structure comprises a plurality of sub units respectively disposed in the sub-pixel regions.

5. The organic electroluminescent display device of claim 4, wherein the light control structure comprises an array substrate, and the array substrate comprises a plurality of switching units configured to control the amount of the light beam passing through each of the sub units and entering the organic light emitting structure.

6. The organic electroluminescent display device of claim 5, wherein each of the switching units comprises a thin film transistor.

7. The organic electroluminescent display device of claim 4, wherein the photo current sensitive layer comprises a plurality of photo current sensitive units respectively disposed in the sub-pixel regions.

8. The organic electroluminescent display device of claim 1, wherein the first electrode is an anode electrode, and the second electrode is a cathode electrode.

9. The organic electroluminescent display device of claim 4, wherein the first electrode comprises a plurality of first sub electrodes respectively disposed in the sub-pixel regions.

10. The organic electroluminescent display device of claim 8, wherein the organic light emitting structure further comprises:
a hole transport layer, disposed between the organic light emitting layer and the photo current sensitive layer; and
an electron transport layer, disposed between the organic light emitting layer and the second electrode.

11. The organic electroluminescent display device of claim 1, wherein the photo current sensitive layer comprises a tin phthalocyanine (SnPc) or a mixed film of SnPc and carbon-60 (SnPc: C₆₀ mixed film).
